(19) United States
(12) Patent Application Publication
(10) Pub. No.: US 2026/0114155 A1
(43) Pub. Date: Apr. 23, 2026

(54) WINDOW MODULE AND ELECTRONIC DEVICE INCLUDING THE SAME

(71) Applicant: Samsung Display Co., Ltd., Yongin-si (KR)

(72) Inventors: TAEHEE KIM, Yongin-si (KR); JINSOO SHIN, Yongin-si (KR); JEONG SEOK LEE, Yongin-si (KR); HYUNHO JEONG, Yongin-si (KR); JONGSEOK JOO, Yongin-si (KR)

(21) Appl. No.: 19/275,838

(22) Filed: Jul. 21, 2025

(30) Foreign Application Priority Data
Oct. 17, 2024 (KR) 10-2024-0141722

(51) Int. Cl. H10K 59/80; C03C 17/34; G02B 1/11; G02B 1/14

(52) U.S. Cl. CPC H10K 59/873; C03C 17/3429; G02B 1/11; G02B 1/14; H10K 59/879; C03C 2217/213; C03C 2217/281; C03C 2217/734; C03C 2217/76; C03C 2218/156

(57) ABSTRACT

A window module includes: a window; at least one bottom high refractive layer on the window; at least one bottom low refractive layer on the bottom high refractive layer; a top high refractive layer on the bottom low refractive layer; a capping layer on the top high refractive layer; and an anti-fingerprint layer on the capping layer. A distance between a top surface of the anti-fingerprint layer and a top surface of the top high refractive layer is less than about 200 nm.

### CROSS-REFERENCE TO RELATED APPLICATION

The present application claims priority to and the benefit of Korean Patent Application No. 10-2024-0141722, filed on Oct. 17, 2024, in the Korean Intellectual Property Office, the entire disclosure of which is incorporated by reference herein.

### BACKGROUND

### 1. Field

Aspects of embodiments of the present disclosure relate to a window module, and an electronic device including the window module.

### 2. Description of the Related Art

A display device includes a display panel, and a window arranged on the display panel. In order to improve a display quality of the display device, a structure capable of reducing a reflectivity of the display device is being developed. For example, a structure in which a polarizing plate is further arranged between the display panel and the window may be provided, but this structure may reduce a luminous efficiency of the display panel.

The above information disclosed in this Background section is for enhancement of understanding of the background of the present disclosure, and therefore, it may contain information that does not constitute prior art.

### SUMMARY

Embodiments of the present disclosure may be directed to a window module having an improved display quality.

Embodiments of the present disclosure may be directed to a display device including the window module.

Embodiments of the present disclosure may be directed to an electronic device including the display device.

According to one or more embodiments of the present disclosure, a window module includes: a window; at least one bottom high refractive layer on the window; at least one bottom low refractive layer on the bottom high refractive layer; a top high refractive layer on the bottom low refractive layer; a capping layer on the top high refractive layer; and an anti-fingerprint layer on the capping layer. A distance between a top surface of the anti-fingerprint layer and a top surface of the top high refractive layer is less than about 200 nm.

In an embodiment, the distance between the top surface of the anti-fingerprint layer and the top surface of the top high refractive layer may be less than a thickness of the top high refractive layer.

In an embodiment, the window module may further include a top low refractive layer between the top high refractive layer and the capping layer.

In an embodiment, a sum of a thickness of the top low refractive layer, a thickness of the capping layer, and a thickness of the anti-fingerprint layer may be same as the distance between the top surface of the anti-fingerprint layer and the top surface of the top high refractive layer.

In an embodiment, the bottom high refractive layer may include a first bottom high refractive layer having a first thickness, a second bottom high refractive layer having a second thickness, and a third bottom high refractive layer having a third thickness, and a thickness of the top high refractive layer may be greater than each of the first to third thicknesses.

In an embodiment, the thickness of the top high refractive layer may be greater than a sum of the first to third thicknesses.

In an embodiment, the first bottom high refractive layer may be on the window, the second bottom high refractive layer may be on the first bottom high refractive layer, and the third bottom high refractive layer may be on the second bottom high refractive layer.

In an embodiment, the second thickness may be greater than the third thickness, and the third thickness may be greater than the first thickness.

In an embodiment, the bottom low refractive layer may include a first bottom low refractive layer having a fourth thickness, a second bottom low refractive layer having a fifth thickness, and a third bottom low refractive layer having a sixth thickness, and the thickness of the top high refractive layer may be greater than each of the fourth to sixth thicknesses.

In an embodiment, the thickness of the top high refractive layer may be greater than a sum of the fourth to sixth thicknesses.

In an embodiment, the first bottom low refractive layer may be on the first bottom high refractive layer, the second bottom low refractive layer may be on the second bottom high refractive layer, and the third bottom low refractive layer may be on the third bottom high refractive layer.

In an embodiment, the fourth thickness may be greater than the fifth thickness, and the fifth thickness may be greater than the sixth thickness.

In an embodiment, a refractive index of each of the bottom high refractive layer and the top high refractive layer may be about 1.9 to about 2.3.

In an embodiment, the bottom high refractive layer and the top high refractive layer may each include aluminum silicon nitride (Al—Si—N).

In an embodiment, a refractive index of the bottom low refractive layer may be about 1.41 to about 1.54.

In an embodiment, the bottom low refractive layer may include silicon oxide (Si—O).

According to one or more embodiments of the present disclosure, a window module includes: a window; at least one bottom high refractive layer on the window at least one bottom low refractive layer on the bottom high refractive layer; a top high refractive layer on the bottom low refractive layer; a capping layer on the top high refractive layer; and an anti-fingerprint layer on the capping layer. A thickness of the top high refractive layer is greater than each of a thickness of the bottom high refractive layer and a thickness of the bottom low refractive layer.

In an embodiment, the window module may further include a top low refractive layer between the top high refractive layer and the capping layer.

In an embodiment, a sum of a thickness of the top low refractive layer, a thickness of the capping layer, and a thickness of the anti-fingerprint layer may be same as a distance between a top surface of the anti-fingerprint layer and a top surface of the top high refractive layer.

According to one or more embodiments of the present disclosure, an electronic device includes: a display device; and a power module configured to provide power to the display device. The display device includes: a display panel configured to display an image; and a window module on the display panel. The window module includes: a window; at least one bottom high refractive layer on the window; at least one bottom low refractive layer on the bottom high refractive layer; a top high refractive layer on the bottom low refractive layer; a capping layer on the top high refractive layer; and an anti-fingerprint layer on the capping layer. A distance between a top surface of the anti-fingerprint layer and a top surface of the top high refractive layer is less than about 200 nm.

According to some embodiments of the present disclosure, a window module may include high refractive layers and low refractive layers that are stacked on each other. The high refractive layers may include a bottom high refractive layer and a top high refractive layer, and the low refractive layers may include a bottom low refractive layer and a top low refractive layer. The top high refractive layer may be arranged at an uppermost part of the high refractive layers formed in the window module, and may have a largest thickness.

According to some embodiments of the present disclosure, because the top high refractive layer having a high refractive index has a relatively high hardness, even if a pressure is applied to a surface of the window module, scratches may not occur deeply. In addition, because the bottom high refractive layer, the bottom low refractive layer, the top high refractive layer, and the top low refractive layer may be alternately stacked on one another, a display quality of the display device may be improved.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a cross-sectional view illustrating a display device according to an embodiment of the present disclosure.

FIG. 2 is a cross-sectional view illustrating a display panel included in the display device of FIG. 1.

FIG. 3 is a cross-sectional view illustrating a window module included in the display device of FIG. 1.

FIG. 4 is a flowchart illustrating a method of manufacturing the display device of FIG. 1.

FIGS. 5-15 are cross-sectional views illustrating some processes of the method of FIG. 4.

FIG. 16 is a block diagram illustrating an electronic device according to an embodiment of the present disclosure.

FIG. 17 is a schematic diagram of some electronic devices according to various embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

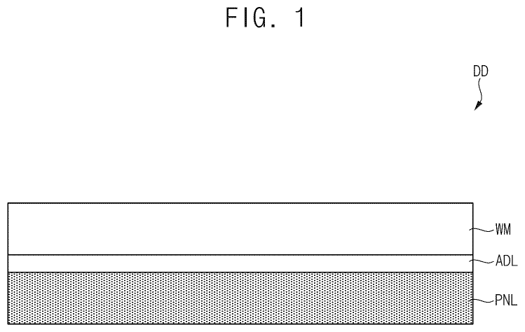

FIG. 1 is a cross-sectional view illustrating a display device according to an embodiment of the present disclosure.

Referring to FIG. 1, a display device DD according to an embodiment of the present disclosure may include a display panel PNL, an adhesive layer ADL, and a window module (e.g., a window assembly) WM.

The display panel PNL may include a transistor, and a light emitting diode disposed on the transistor. The light emitting diode may be electrically connected to the transistor. The transistor may generate a driving current, and the light emitting diode may emit light corresponding to the driving current. Accordingly, the display panel PNL may display an image.

The adhesive layer ADL may be disposed on the display panel PNL. The adhesive layer ADL may adhere the display panel PNL and the window module WM to each other. In an embodiment, the adhesive layer ADL may be formed of an adhesive material. For example, the adhesive layer ADL may include a pressure sensitive adhesive (PSA), an optically clear adhesive (OCA), an optically clear resin (OCR), or the like. These may be used alone or in any suitable combination with each other.

The window module WM may be disposed on the adhesive layer ADL.

The window module WM may perform a function of improving a display quality of the display device DD. For example, as the window module WM reflects external light, the quality of an image displayed on the display panel PNL may be improved.

In addition, the window module WM may improve a durability of the display device DD. For example, because the window module WM may have excellent high hardness characteristics, the window module WM may have a high resistance to scratches.

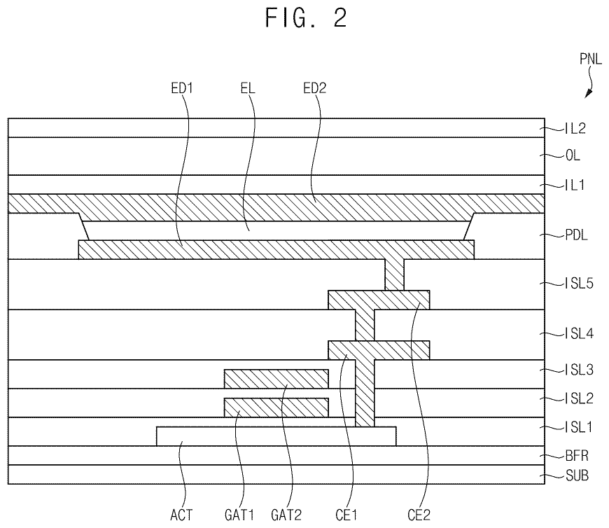

FIG. 2 is a cross-sectional view illustrating a display panel included in the display device of FIG. 1.

Referring to FIG. 2, the display panel PNL may include a substrate SUB, a buffer layer BFR, an active pattern ACT, a first insulating layer ISL1, a first gate electrode GAT1, a second insulating layer ISL2, a second gate electrode GAT2, a third insulating layer ISL3, a first connection electrode CE1, a fourth insulating layer ISL4, a second connection electrode CE2, a fifth insulating layer ISL5, a first electrode ED1, a pixel defining layer PDL, an emission layer EL, a second electrode ED2, a first inorganic layer IL1, an organic layer OL, and a second inorganic layer IL2.

In an embodiment, the substrate SUB may be formed of glass, quartz, a plastic, or the like. Examples of the plastic that may be used for the substrate SUB may include polyimide (PI), polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), and the like. These may be used alone or in any suitable combination with each other.

The buffer layer BFR may be disposed on the substrate SUB. In an embodiment, the buffer layer BFR may be formed of an insulating material. Examples of the insulating material that may be used for the buffer layer BFR may include silicon oxide (Si—O), silicon nitride (Si—N), silicon oxynitride (SiON), and/or the like. These may be used alone or in any suitable combination with each other.

The active pattern ACT may be disposed on the buffer layer BFR. In an embodiment, the active pattern ACT may be formed of an oxide semiconductor, a silicon semiconductor, or the like.

The first insulating layer ISL1 may be disposed on the buffer layer BFR, and may cover the active pattern ACT. In an embodiment, the first insulating layer ISL1 may be formed of an insulating material. Examples of the insulating material that may be used as the first insulating layer ISL1 may include silicon oxide (Si—O), silicon nitride (Si—N), silicon oxynitride (SiON), and/or the like. These may be used alone or in any suitable combination with each other.

The first gate electrode GAT1 may be disposed on the first insulating layer ISL1, and may overlap with the active pattern ACT. In an embodiment, the first gate electrode GAT1 may be formed of a metal, an alloy, a conductive metal oxide, a transparent conductive material, or the like. Examples of the materials that may be used as the first gate electrode GAT1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in any suitable combination with each other.

The second insulating layer ISL2 may be disposed on the first insulating layer ISL1, and may cover the first gate electrode GAT1. In an embodiment, the second insulating layer ISL2 may be formed of an insulating material. Examples of the insulating material that may be used as the second insulating layer ISL2 may include silicon oxide (Si—O), silicon nitride (Si—N), silicon oxynitride (SiON), and/or the like. These may be used alone or in any suitable combination with each other.

The second gate electrode GAT2 may be disposed on the second insulating layer ISL2, and may overlap with the first gate electrode GAT1. In an embodiment, the second gate electrode GAT2 may be formed of a metal, an alloy, a conductive metal oxide, a transparent conductive material, or the like.

The third insulating layer ISL3 may be disposed on the second insulating layer ISL2, and may cover the second gate electrode GAT2. In an embodiment, the third insulating layer ISL3 may be formed of an insulating material. Examples of the insulating material that may be used as the third insulating layer ISL3 may include silicon oxide (Si—O), silicon nitride (Si—N), silicon oxynitride (SiON), and/or the like. These may be used alone or in any suitable combination with each other.

The first connection electrode CE1 may be disposed on the third insulating layer ISL3, and may contact the active pattern ACT. In an embodiment, the first connection electrode CE1 may be formed of a metal, an alloy, a conductive metal oxide, a transparent conductive material, or the like. Examples of the materials that may be used as the first connection electrode CE1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in any suitable combination with each other.

The fourth insulating layer ISL4 may be disposed on the third insulating layer ISL3, and may cover the first connection electrode CE1. In an embodiment, the fourth insulating layer ISL4 may be formed of an insulating material. Examples of the insulating material that may be used as the fourth insulating layer ISL4 may include a photoresist, a polyacrylic resin, a polyimide resin, an acrylic resin, and/or the like. These may be used alone or in any suitable combination with each other.

The second connection electrode CE2 may be disposed on the fourth insulating layer ISL4, and may contact the first connection electrode CE1. In an embodiment, the second connection electrode CE2 may be formed of a metal, an alloy, a conductive metal oxide, a transparent conductive material, or the like.

The fifth insulating layer ISL5 may be disposed on the fourth insulating layer ISL4, and may cover the second connection electrode CE2. In an embodiment, the fifth insulating layer ISL5 may be formed of an insulating material. Examples of the insulating material that may be used as the fifth insulating layer ISL5 may include a photoresist, a polyacrylic resin, a polyimide resin, an acrylic resin, and/or the like. These may be used alone or in any suitable combination with each other.

The first electrode ED1 may be disposed on the fifth insulating layer ISL5, and may contact the second connection electrode CE2. In an embodiment, the first electrode ED1 may be formed of a metal, an alloy, a conductive metal oxide, a transparent conductive material, or the like. Examples of the materials that may be used as the first electrode ED1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in any suitable combination with each other.

The pixel defining layer PDL may be disposed on the fifth insulating layer ISL5. An opening exposing the first electrode ED1 may be formed in the pixel defining layer PDL. The pixel defining layer PDL may be formed of an insulating material. Examples of the insulating material that may be used as the pixel defining layer PDL may include a photoresist, a polyacrylic resin, a polyimide resin, an acrylic resin, and/or the like. These may be used alone or in any suitable combination with each other.

The emission layer EL may be disposed on the first electrode ED1. The emission layer EL may generate light based on a voltage difference between the first electrode ED1 and the second electrode ED2. For example, the emission layer EL may include an organic material that generates light.

The second electrode ED2 may be disposed on the emission layer EL, and may receive a common voltage. In an embodiment, the second electrode ED2 may be formed of a metal, an alloy, a conductive metal oxide, a transparent conductive material, or the like.

The first inorganic layer IL1 may be disposed on the second electrode ED2. In an embodiment, the first inorganic layer IL1 may be formed of an inorganic material.

The organic layer OL may be disposed on the first inorganic layer IL1. In an embodiment, the organic layer OL may be formed of an organic material.

The second inorganic layer IL2 may be disposed on the organic layer OL. In an embodiment, the second inorganic layer IL2 may be formed of an inorganic material.

The first inorganic layer IL1, the organic layer OL, and the second inorganic layer IL2 may prevent or substantially prevent moisture and/or oxygen from penetrating into the emission layer EL.

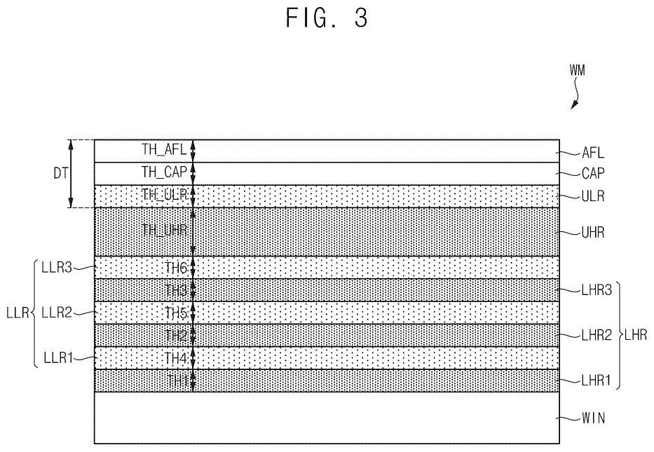

FIG. 3 is a cross-sectional view illustrating a window module included in the display device of FIG. 1.

Referring to FIG. 3, the window module WM may include a window WIN, a bottom high refractive layer LHR, a bottom low refractive layer LLR, a top high refractive layer UHR, a top low refractive layer ULR, a capping layer CAP, and an anti-fingerprint layer AFL.

The bottom high refractive layer LHR may include a first bottom high refractive layer LHR1, a second bottom high refractive layer LHR2, and a third bottom high refractive layer LHR3. The bottom low refractive layer LLR may include a first bottom low refractive layer LLR1, a second bottom low refractive layer LLR2, and a third bottom low refractive layer LLR3.

However, the present disclosure is not limited thereto, and the number of high refractive layers and the number of low refractive layers may be variously modified as needed or desired.

The window WIN may be disposed on the adhesive layer ADL. In an embodiment, the window WIN may be formed of glass, quartz, a plastic, or the like. Examples of the materials that may be used as the window WIN may include polyimide (PI), polyethylene terephthalate (PET), polyethylene naphthalene (PEN), polypropylene (PP), polycarbonate (PC), polystyrene (PS), polysulfone (PSul), polyethylene (PE), polyphthalamide (PPA), polyethersulfone (PES), polyarylate (PAR), polycarbonate oxide (PCO), modified polyphenylene oxide (MPPO), and the like. These may be used alone or in any suitable combination with each other.

The first bottom high refractive layer LHR1 may be disposed on the window WIN. In an embodiment, the first bottom high refractive layer LHR1 may contact the window WIN. For example, the first bottom high refractive layer LHR1 may be coated on the window WIN.

In an embodiment, the first bottom high refractive layer LHR1 may have a relatively high refractive index. For example, the refractive index of the first bottom high refractive layer LHR1 may be about 1.9 to about 2.3.

In an embodiment, the first bottom high refractive layer LHR1 may have a first thickness TH1 that is less than a thickness TH_UHR of the top high refractive layer UHR. For example, the first thickness TH1 may be about 15 nm to 25 nm. In more detail, the first thickness TH1 may be about 21 nm.

In an embodiment, the first bottom high refractive layer LHR1 may include a metal-inorganic compound. Examples of metal materials that may be used as the first bottom high refractive layer LHR1 may include aluminum (Al), magnesium (Mg), tantalum (Ta), hafnium (Hf), zinc (Zn), tungsten (W), copper (Cu), silver (Ag), gold (Au), platinum (Pt), iron (Fe), titanium (Ti), gallium (Ga), and the like. Examples of inorganic compounds that may be used as the first bottom high refractive layer LHR1 may include silicon oxide (Si—O), silicon nitride (Si—N), silicon oxynitride (Si—O—N), and the like. These may be used alone or in any suitable combination with each other. In more detail, the first bottom high refractive layer LHR1 may include aluminum silicon nitride (Al—Si—N).

The first bottom low refractive layer LLR1 may be disposed on the first bottom high refractive layer LHR1. In an embodiment, the first bottom low refractive layer LLR1 may contact the first bottom high refractive layer LHR1. For example, the first bottom low refractive layer LLR1 may be coated on the first bottom high refractive layer LHR1.

In an embodiment, the first bottom low refractive layer LLR1 may have a relatively low refractive index. For example, the refractive index of the first bottom low refractive layer LLR1 may be about 1.41 to about 1.54.

In an embodiment, the first bottom low refractive layer LLR1 may have a fourth thickness TH4 that is less than the thickness TH_UHR of the top high refractive layer UHR. For example, the fourth thickness TH4 may be about 26 nm to about 44 nm. In more detail, the fourth thickness TH4 may be about 35 nm.

In an embodiment, the first bottom low refractive layer LLR1 may include an inorganic compound. Examples of the inorganic compound that may be used as the first bottom low refractive layer LLR1 may include silicon oxide (Si—O), silicon nitride (Si—N), silicon oxynitride (Si—O—N), aluminum oxide (Al—O), titanium oxide (Ti—O), tantalum oxide (Ta—O), hafnium oxide (Hf—O), zinc oxide (Zn—O), and/or the like. These may be used alone or in any suitable combination with each other. In more detail, the first bottom low refractive layer LLR1 may include silicon oxide (Si—O).

The second bottom high refractive layer LHR2 may be disposed on the first bottom low refractive layer LLR1. In an embodiment, the second bottom high refractive layer LHR2 may contact the first bottom low refractive layer LLR1. For example, the second bottom high refractive layer LHR2 may be coated on the first bottom low refractive layer LLR1.

In an embodiment, the second bottom high refractive layer LHR2 may have a relatively high refractive index. For example, the refractive index of the second bottom high refractive layer LHR2 may be about 1.9 to about 2.3.

In an embodiment, the second bottom high refractive layer LHR2 may have a second thickness TH2 that is smaller than the thickness TH_UHR of the top high refractive layer UHR. For example, the second thickness TH2 may be about 157 nm to 197 nm. In more detail, the second thickness TH2 may be about 177 nm.

In an embodiment, the second bottom high refractive layer LHR2 may include a metal-inorganic compound. Examples of metal materials that may be used as the second bottom high refractive layer LHR2 may include aluminum (Al), magnesium (Mg), tantalum (Ta), hafnium (Hf), zinc (Zn), tungsten (W), copper (Cu), silver (Ag), gold (Au), platinum (Pt), iron (Fe), titanium (Ti), gallium (Ga), and the like. Examples of inorganic compounds that may be used as the second bottom high refractive layer LHR2 may include silicon oxide (Si—O), silicon nitride (Si—N), silicon oxynitride (Si—O—N), and the like. These may be used alone or in any suitable combination with each other. In more detail, the second bottom high refractive layer LHR2 may include aluminum silicon nitride (Al—Si—N).

The second bottom low refractive layer LLR2 may be disposed on the second bottom high refractive layer LHR2. In an embodiment, the second bottom low refractive layer LLR2 may contact the second bottom high refractive layer LHR2. For example, the second bottom low refractive layer LLR2 may be coated on the second bottom high refractive layer LHR2.

In an embodiment, the second bottom low refractive layer LLR2 may have a relatively low refractive index. For example, the refractive index of the second bottom low refractive layer LLR2 may be about 1.41 to about 1.54.

In an embodiment, the second bottom low refractive layer LLR2 may have a fifth thickness TH5 that is less than the thickness TH_UHR of the top high refractive layer UHR. For example, the fifth thickness TH5 may be about 18 nm to about 32 nm. In more detail, the fifth thickness TH5 may be about 24 nm.

In an embodiment, the second bottom low refractive layer LLR2 may include an inorganic compound. Examples of the inorganic compound that may be used as the second bottom low refractive layer LLR2 may include silicon oxide (Si—O), silicon nitride (Si—N), silicon oxynitride (Si—O—N), aluminum oxide (Al—O), titanium oxide (Ti—O), tantalum oxide (Ta—O), hafnium oxide (Hf—O), zinc oxide (Zn—O), and/or the like. These may be used alone or in any suitable combination with each other. In more detail, the second bottom low refractive layer LLR2 may include silicon oxide (Si—O).

The third bottom high refractive layer LHR3 may be disposed on the second bottom low refractive layer LLR2. In an embodiment, the third bottom high refractive layer LHR3 may contact the second bottom low refractive layer LLR2. For example, the third bottom high refractive layer LHR3 may be coated on the second bottom low refractive layer LLR2.

In an embodiment, the third bottom high refractive layer LHR3 may have a relatively high refractive index. For example, the refractive index of the third bottom high refractive layer LHR3 may be about 1.9 to about 2.3.

In an embodiment, the third bottom high refractive layer LHR3 may have a third thickness TH3 that is less than the thickness TH_UHR of the top high refractive layer UHR. For example, the third thickness TH3 may be about 41 nm to 69 nm. In more detail, the third thickness TH3 may be about 54 nm.

In an embodiment, the second thickness TH2 may be greater than the third thickness TH3, and the third thickness TH3 may be greater than the first thickness TH1.

In an embodiment, the third bottom high refractive layer LHR3 may include a metal-inorganic compound. Examples of metal materials that may be used as the third bottom high refractive layer LHR3 may include aluminum (Al), magnesium (Mg), tantalum (Ta), hafnium (Hf), zinc (Zn), tungsten (W), copper (Cu), silver (Ag), gold (Au), platinum (Pt), iron (Fe), titanium (Ti), gallium (Ga), and the like. Examples of inorganic compounds that may be used as the third bottom high refractive layer LHR3 may include silicon oxide (Si—O), silicon nitride (Si—N), silicon oxynitride (Si—O—N), and the like. These may be used alone or in any suitable combination with each other. In more detail, the third bottom high refractive layer LHR3 may include aluminum silicon nitride (Al—Si—N).

The third bottom low refractive layer LLR3 may be disposed on the third bottom high refractive layer LHR3. In an embodiment, the third bottom low refractive layer LLR3 may contact the third bottom high refractive layer LHR3. For example, the third bottom low refractive layer LLR3 may be coated on the third bottom high refractive layer LHR3.

In an embodiment, the third bottom low refractive layer LLR3 may have a relatively low refractive index. For example, the refractive index of the third bottom low refractive layer LLR3 may be about 1.41 to about 1.54.

In an embodiment, the third bottom low refractive layer LLR3 may have a sixth thickness TH6 that is less than the thickness TH_UHR of the top high refractive layer UHR. For example, the sixth thickness TH6 may be about 17 nm to about 29 nm. In more detail, the sixth thickness TH6 may be about 23 nm.

In an embodiment, the fourth thickness TH4 may be greater than the fifth thickness TH5, and the fifth thickness TH5 may be greater than the sixth thickness TH6.

In an embodiment, the third bottom low refractive layer LLR3 may include an inorganic compound. Examples of the inorganic compound that may be used as the third bottom low refractive layer LLR3 may include silicon oxide (Si—O), silicon nitride (Si—N), silicon oxynitride (Si—O—N), aluminum oxide (Al—O), titanium oxide (Ti—O), tantalum oxide (Ta—O), hafnium oxide (Hf—O), zinc oxide (Zn—O), and the like. These may be used alone or in any suitable combination with each other. In more detail, the third bottom low refractive layer LLR3 may include silicon oxide (Si—O).

The top high refractive layer UHR may be disposed on the third bottom low refractive layer LLR3. In an embodiment, the top high refractive layer UHR may contact the third bottom low refractive layer LLR3. For example, the top high refractive layer UHR may be coated on the third bottom low refractive layer LLR3.

In an embodiment, the top high refractive layer UHR may have a relatively high refractive index. For example, the refractive index of the top high refractive layer UHR may be from about 1.9 to about 2.3.

In an embodiment, the top high refractive layer UHR may have a relatively large thickness TH_UHR. For example, the thickness TH_UHR of the top high refractive layer UHR may be about 225 nm to about 375 nm. In more detail, the thickness TH_UHR of the top high refractive layer UHR may be about 300 nm.

In an embodiment, the top high refractive layer UHR may include a metal-inorganic compound. Examples of metal materials that may be used as the top high refractive layer UHR may include aluminum (Al), magnesium (Mg), tantalum (Ta), hafnium (Hf), zinc (Zn), tungsten (W), copper (Cu), silver (Ag), gold (Au), platinum (Pt), iron (Fe), titanium (Ti), gallium (Ga), and/or the like. Examples of inorganic compounds that may be used as the top high refractive layer UHR may include silicon oxide (Si—O), silicon nitride (Si—N), silicon oxynitride (Si—O—N), and/or the like. These may be used alone or in any suitable combination with each other. In more detail, the top high refractive layer UHR may include aluminum silicon nitride (Al—Si—N).

The top low refractive layer ULR may be disposed on the top high refractive layer UHR. In an embodiment, the top low refractive layer ULR may contact the top high refractive layer UHR. For example, the top low refractive layer ULR may be coated on the top high refractive layer UHR.

In an embodiment, the top low refractive layer ULR may have a relatively low refractive index. For example, the refractive index of the top low refractive layer ULR may be from about 1.41 to about 1.54.

In an embodiment, the top low refractive layer ULR may have a thickness TH_ULR that is less than the thickness TH_UHR of the top high refractive layer UHR. For example, the thickness TH_ULR of the top low refractive layer ULR may be about 37 nm to about 63 nm. In more detail, the thickness TH_ULR of the top low refractive layer ULR may be about 51 nm.

In an embodiment, the top low refractive layer ULR may include an inorganic compound. Examples of the inorganic compound that may be used as the top low refractive layer ULR may include silicon oxide (Si—O), silicon nitride (Si—N), silicon oxynitride (Si—O—N), aluminum oxide (Al—O), titanium oxide (Ti—O), tantalum oxide (Ta—O), hafnium oxide (Hf—O), zinc oxide (Zn—O), and the like. These may be used alone or in any suitable combination with each other. In more detail, the top low refractive layer ULR may include silicon oxide (Si—O).

The capping layer CAP may be disposed on the top low refractive layer ULR. In an embodiment, the capping layer CAP may contact the top low refractive layer ULR. For example, the capping layer CAP may be coated on the top low refractive layer ULR.

In an embodiment, the capping layer CAP may have a thickness TH_CAP that is less than the thickness TH_UHR of the top high refractive layer UHR. For example, the thickness TH_CAP of the capping layer CAP may be about 40 nm to about 50 nm. In more detail, the thickness TH_CAP of the capping layer CAP may be about 43 nm.

In an embodiment, the capping layer CAP may include an inorganic compound. Examples of the inorganic compound that may be used as the capping layer CAP may include silicon oxide (Si—O), silicon nitride (Si—N), silicon oxynitride (Si—O—N), aluminum oxide (Al—O), titanium oxide (Ti—O), tantalum oxide (Ta—O), hafnium oxide (Hf—O), zinc oxide (Zn—O), and the like. These may be used alone or in any suitable combination with each other.

The anti-fingerprint layer AFL may be disposed on the capping layer CAP. In an embodiment, the anti-fingerprint layer AFL may contact the capping layer CAP. For example, the anti-fingerprint layer AFL may be formed by coating an anti-fingerprint material on the capping layer CAP. Examples of the anti-fingerprint material that may be used as the anti-fingerprint layer AFL may include a metal oxide (e.g., titanium oxide (Ti—O)), a silicon-based compound, a fluorine-based compound, and the like.

In an embodiment, the anti-fingerprint layer AFL may have a thickness TH_AFL that is less than the thickness TH_UHR of the top high refractive layer UHR. For example, the thickness TH_AFL of the anti-fingerprint layer AFL may be about 10 nm to about 30 nm. In more detail, the thickness TH_AFL of the anti-fingerprint layer AFL may be about 20 nm.

In an embodiment, a sum of the thickness TH_ULR of the top low refractive layer ULR, the thickness TH_CAP of the capping layer CAP, and the thickness TH_AFL of the anti-fingerprint layer AFL may be the same or substantially same as a distance DT from a top surface of the anti-fingerprint layer AFL to a top surface of the top high refractive layer UHR.

In an embodiment, the distance DT from the top surface of the anti-fingerprint layer AFL to the top surface of the top high refractive layer UHR may be less than about 200 nm. For example, the distance DT from the top surface of the anti-fingerprint layer AFL to the top surface of the top high refractive layer UHR may be about 100 nm to about 150 nm.

In an embodiment, the distance DT from the top surface of the anti-fingerprint layer AFL to the top surface of the top high refractive layer UHR may be less than the thickness TH_UHR of the top high refractive layer UHR.

In an embodiment, the thickness TH_UHR of the top high refractive layer UHR may be greater than each of the first to sixth thicknesses TH1, TH2, TH3, TH4, TH5, and TH6. For example, the thickness TH_UHR of the top high refractive layer UHR may be greater than a sum of the first to third thicknesses TH1, TH2, and TH3. In addition, the thickness TH_UHR of the top high refractive layer UHR may be greater than the sum of the fourth to sixth thicknesses TH4, TH5, and TH6.

In addition, the thickness TH_UHR of the top high refractive layer UHR may be greater than each of the thickness TH_ULR of the top low refractive layer ULR, the thickness TH_CAP of the capping layer CAP, and the thickness TH_AFL of the anti-fingerprint layer AFL.

In addition, an additional high refractive layer may not be disposed on top of the top high refractive layer UHR. In other words, the top high refractive layer UHR may be disposed at the uppermost part of the high refractive layers formed in the window module WM.

In other words, the top high refractive layer UHR having a relatively larger thickness may be arranged at the uppermost part of the high refractive layers, so as to be closer to the surface of the window module WM. Because the top high refractive layer UHR having a high refractive index has a relatively high hardness, even if a pressure is applied to the surface of the window module WM, a deep scratch may not occur. For example, the window module WM may have a scratch resistance of about 14 GPa or more, as measured by a Berkovich Indenter hardness test, along an indentation depth of about 50 nm.

However, the present disclosure is not limited thereto. For example, in order to improve the hardness of the window module WM, the hardness of another layer that is disposed relatively upper may be improved. In an embodiment, as the anti-fingerprint layer AFL further includes aluminum (Al), the hardness of the anti-fingerprint layer AFL may be improved. In another embodiment, as an upper film including aluminum (Al) may be further formed, the hardness of the window module WM may be further improved.

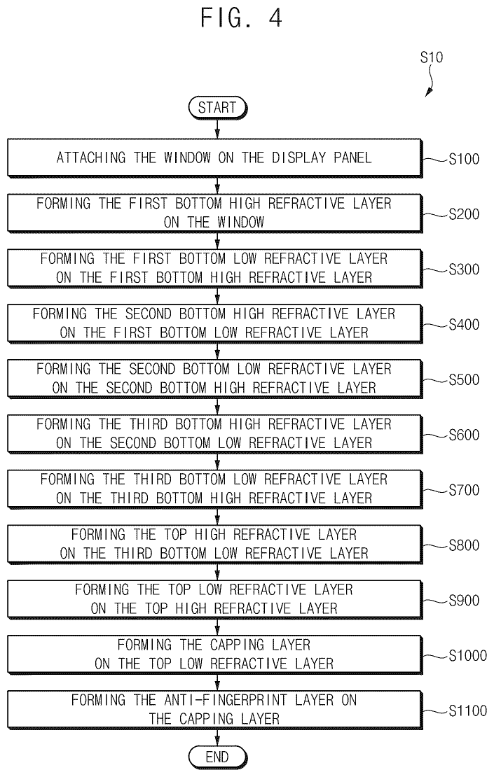

FIG. 4 is a flowchart illustrating a method of manufacturing the display device of FIG. 1.

Referring to FIG. 4, a method (S10) for manufacturing the display device DD may start, and the window WIN may be attached on the display panel PNL (S100). The first bottom high refractive layer LHR1 may be formed on the window WIN (S200), and the first bottom low refractive layer LLR1 may be formed on the first bottom high refractive layer LHR1 (S300). The second bottom high refractive layer LHR2 may be formed on the first bottom low refractive layer LLR1 (S400), and the second bottom low refractive layer LLR2 may be formed on the second bottom high refractive layer LHR2 (S500). The third bottom high refractive layer LHR3 may be formed on the second bottom low refractive layer LLR2 (S600), and the third bottom low refractive layer LLR3 may be formed on the third bottom high refractive layer LHR3 (S700). The top high refractive layer UHR may be formed on the third bottom low refractive layer LLR3 (S800), and the top low refractive layer ULR may be formed on the top high refractive layer UHR (S900). The capping layer CAP may be formed on the top low refractive layer ULR (S1000), the anti-fingerprint layer AFL may be formed on the capping layer CAP (S1100), and the method (S10) may end.

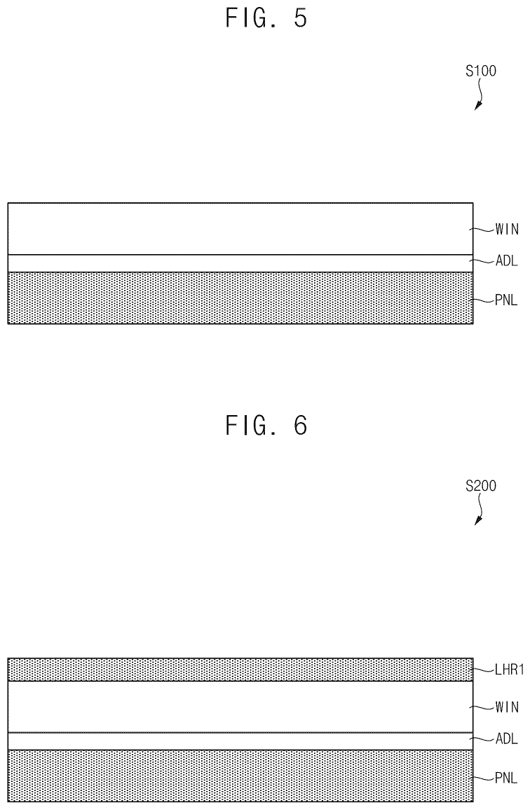

FIGS. 5 through 15 are cross-sectional views illustrating some process of the method of FIG. 4.

Referring to FIG. 5, the window WIN may be adhered on the display panel PNL (S100). In an embodiment, the adhesive layer ADL may be applied onto the display panel PNL, and the window WIN may be adhered on the display panel PNL through the adhesive layer ADL.

Referring to FIG. 6, the first bottom high refractive layer LHR1 may be formed on the window WIN (S200). In an embodiment, the first bottom high refractive layer LHR1 may include aluminum silicon nitride (Al—Si—N), and may have a thickness of about 21 nm.

For example, the first bottom high refractive layer LHR1 may be formed through a suitable process, such as sputtering, a physical vapor deposition (PVD), a chemical vapor deposition (CVD), or an atomic layer deposition (ALD). In an embodiment, the first bottom high refractive layer LHR1 may be formed through an alternating current (RF) magnetron sputtering process.

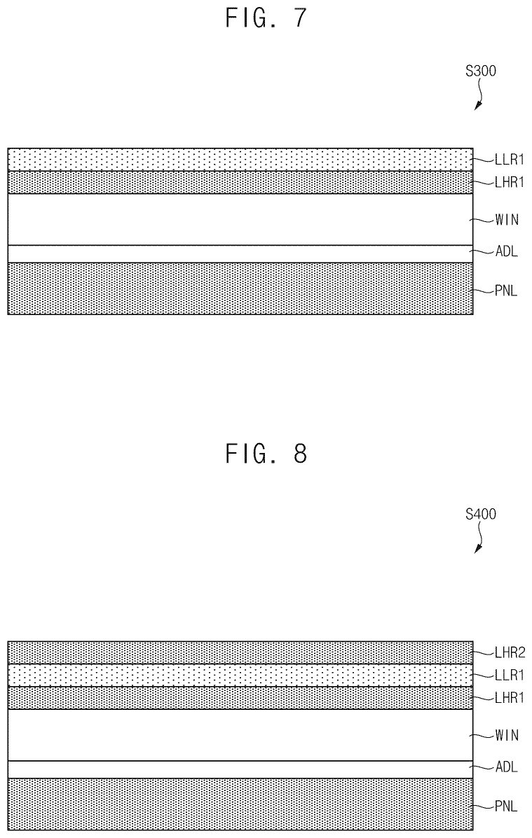

Referring to FIG. 7, the first bottom low refractive layer LLR1 may be formed on the first bottom high refractive layer LHR1 (S300). In an embodiment, the first bottom low refractive layer LLR1 may include silicon oxide (Si—O), and may have a thickness of about 35 nm.

In an embodiment, the first bottom low refractive layer LLR1 may be formed through a RF magnetron sputtering process.

Referring to FIG. 8, the second bottom high refractive layer LHR2 may be formed on the first bottom low refractive layer LLR1 (S400). In an embodiment, the second bottom high refractive layer LHR2 may include aluminum silicon nitride (Al—Si—N), and may have a thickness of about 177 nm.

In an embodiment, the second bottom high refractive layer LHR2 may be formed through a RF magnetron sputtering process.

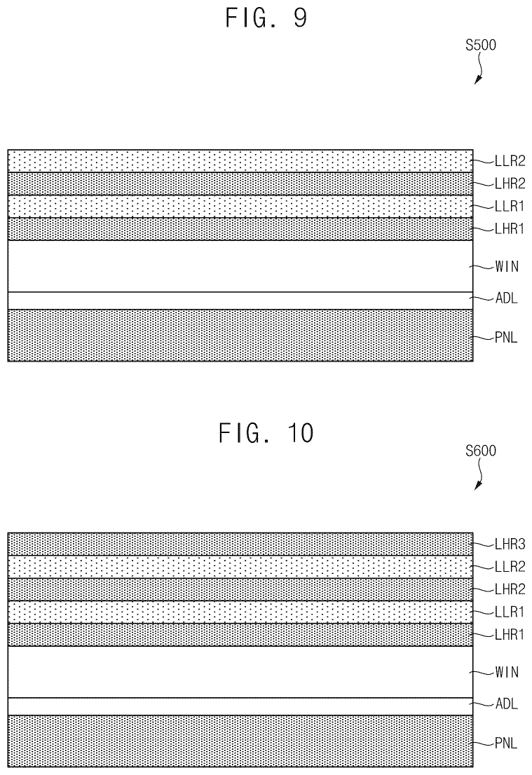

Referring to FIG. 9, the second bottom low refractive layer LLR2 may be formed on the second bottom high refractive layer LHR2 (S500). In an embodiment, the second bottom low refractive layer LLR2 may include silicon oxide (Si—O), and may have a thickness of about 24 nm.

In an embodiment, the second bottom low refractive layer LLR2 may be formed through a RF magnetron sputtering process.

Referring to FIG. 10, the third bottom high refractive layer LHR3 may be formed on the second bottom low refractive layer LLR2 (S600). In an embodiment, the third bottom high refractive layer LHR3 may include aluminum silicon nitride (Al—Si—N), and may have a thickness of about 54 nm.

In an embodiment, the third bottom high refractive layer LHR3 may be formed through a RF magnetron sputtering process.

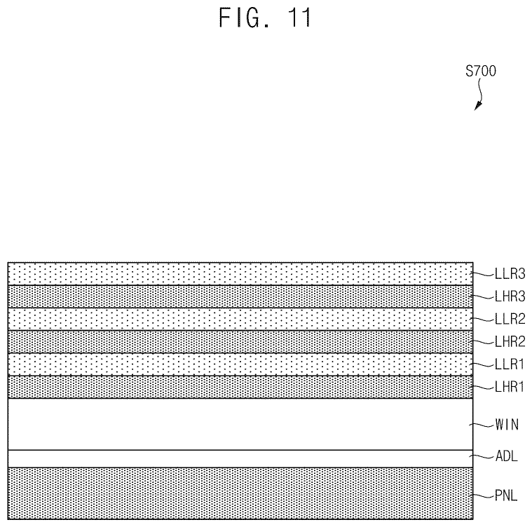

Referring to FIG. 11, the third bottom low refractive layer LLR3 may be formed on the third bottom high refractive layer LHR3 (S700). In an embodiment, the third bottom low refractive layer LLR3 may include silicon oxide (Si—O), and may have a thickness of about 23 nm.

In an embodiment, the third bottom low refractive layer LLR3 may be formed through a RF magnetron sputtering process.

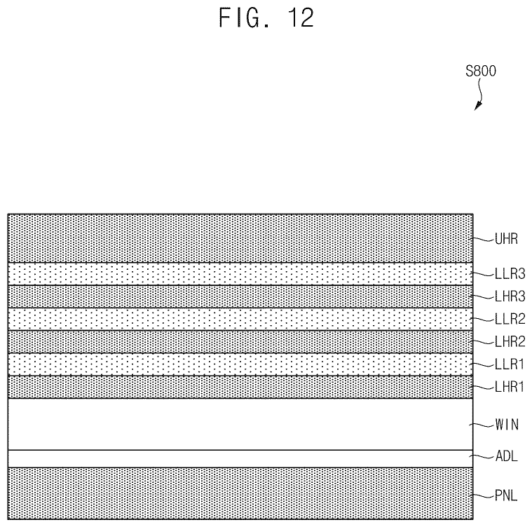

Referring to FIG. 12, the top high refractive layer UHR may be formed on the third bottom low refractive layer LLR3 (S800). In an embodiment, the top high refractive layer UHR may include aluminum silicon nitride (Al—Si—N), and may have a thickness of about 300 nm.

In an embodiment, the top high refractive layer UHR may be formed through a RF magnetron sputtering process.

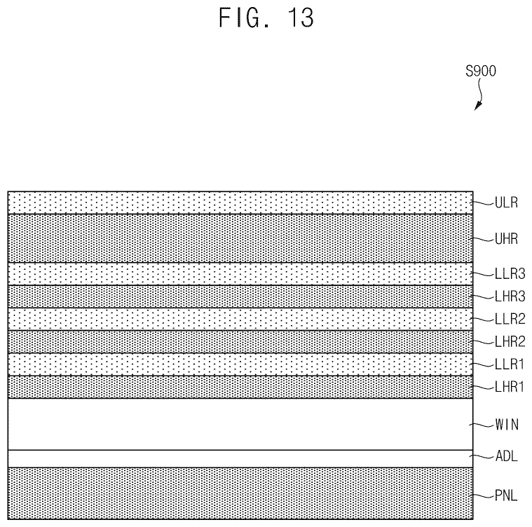

Referring to FIG. 13, the top low refractive layer ULR may be formed on the top high refractive layer UHR (S900). In an embodiment, the top low refractive layer ULR may include silicon oxide (Si—O), and may have a thickness of about 51 nm.

In an embodiment, the top low refractive layer ULR may be formed through a RF magnetron sputtering process.

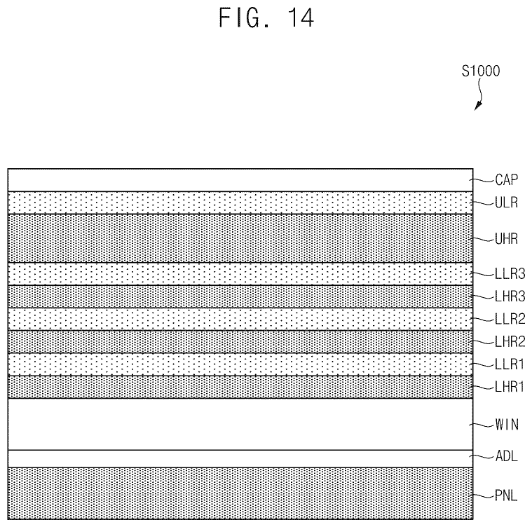

Referring to FIG. 14, the capping layer CAP may be formed on the top low refractive layer ULR (S1000). In an embodiment, the capping layer CAP may include silicon oxide (Si—O), and may have a thickness of about 43 nm.

In an embodiment, the capping layer CAP may be formed through a RF magnetron sputtering process.

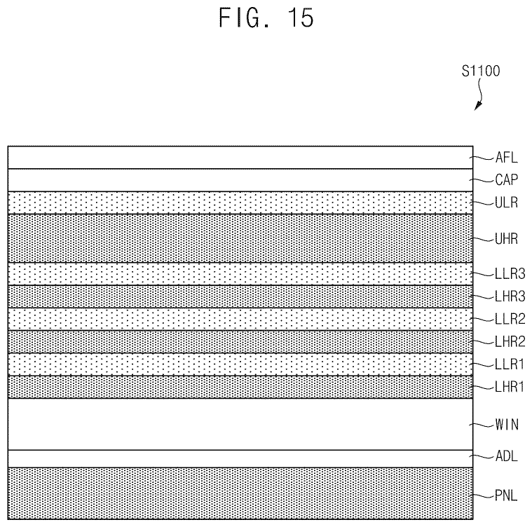

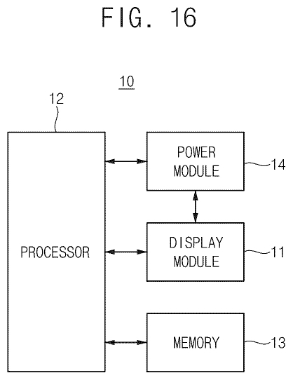

Referring to FIG. 15, the anti-fingerprint layer AFL may be formed on the capping layer CAP (S1100). In an embodiment, the anti-fingerprint layer AFL may include an anti-fingerprint material, and may have a thickness of about 20 nm.

In an embodiment, the anti-fingerprint layer AFL may be formed through an electron beam (E-beam) deposition process.

The display device DD according to some embodiments may be applied to various suitable electronic devices. An electronic device according to an embodiment may include the display device DD as described above, and may further include an additional module or device having additional functions in addition to the display device DD.

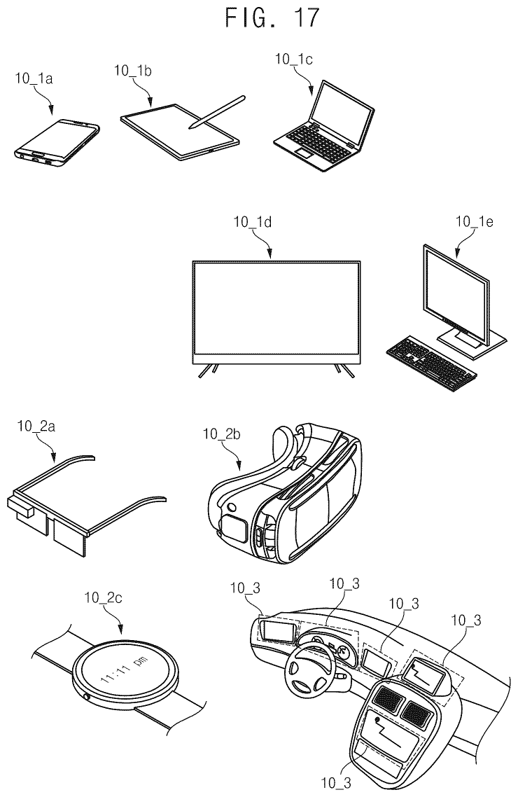

FIG. 16 is a block diagram illustrating an electronic device according to an embodiment of the present disclosure.

Referring to FIG. 16, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information used for an operation of the processor 12 or the display module 11. When the processor 12 executes an application stored in the memory 13, an image data signal and/or an input control signal may be transmitted to the display module 11, and the display module 11 may process the received signal to output image information through a display screen.

The power module 14 may include a power supply module (e.g., a power supply or a power supply circuit), such as a power adapter, a battery device, or the like, and a power conversion module (e.g., a power converter or a power conversion circuit) that converts power supplied by the power supply module to generate power used for an operation of the electronic device 10.

At least one of the components of the electronic device 10 described above may be included in the display device according to some embodiments as described above. In addition, some of individual modules functionally included in one module may be included in the display device, and others may be provided separately from the display device. For example, the display device may include the display module 11, and the processor 12, the memory 13, and the power module 14 may be provided in form of other devices in the electronic device 10 other than the display device.

FIG. 17 is a schematic diagram of some electronic devices according to various embodiments of the present disclosure.

Referring to FIG. 17, various suitable electronic devices to which the display device according to some embodiments may be applied may include an image display electronic device, as well as a wearable electronic device including the display module, a vehicle electronic device 10_3 including the display module, or the like. The image display electronic device may include (e.g., may be) a smartphone 10_1a, a tablet PC 10_1b, a laptop 10_1c, a TV 10_1d, a desk monitor 10_1e, or the like. The wearable electronic device may include (e.g., may be) a smart glasses 10_2a, a head mounted display 10_2b, a smart watch 10_2c, or the like. The vehicle electronic device 10_3 may include (e.g., may be) a center information display (CID) disposed on a dashboard and center fascia of a vehicle, a room mirror display, or the like.

A window module according to an embodiment may include a window, at least one bottom high refractive layer disposed on the window, at least one bottom low refractive layer disposed on the bottom high refractive layer, a top high refractive layer disposed on the bottom low refractive layer, a capping layer disposed on the top high refractive layer, and an anti-fingerprint layer disposed on the capping layer. A distance between a top surface of the anti-fingerprint layer and a top surface of the top high refractive layer may be less than about 200 nm.

In an embodiment, a distance between a top surface of the anti-fingerprint layer and a top surface of the top high refractive layer may be about 100 nm to about 150 nm.

In an embodiment, a distance between a top surface of the anti-fingerprint layer and a top surface of the top high refractive layer may be less than a thickness of the top high refractive layer.

In an embodiment, a thickness of the top high refractive layer may be about 225 nm to about 375 nm.

In an embodiment, the window module may further include a top low refractive layer disposed between the top high refractive layer and the capping layer.

In an embodiment, a sum of a thickness of the top low refractive layer, a thickness of the capping layer, and a thickness of the anti-fingerprint layer may be a same as a distance between a top surface of the anti-fingerprint layer and a top surface of the top high refractive layer.

In an embodiment, the bottom high refractive layer may include a first bottom high refractive layer having a first thickness, a second bottom high refractive layer having a second thickness, and a third bottom high refractive layer having a third thickness, and a thickness of the top high refractive layer may be greater than each of the first to third thicknesses.

In an embodiment, a thickness of the top high refractive layer may be greater than a sum of the first to third thicknesses.

In an embodiment, the first bottom high refractive layer may be disposed on the window, the second bottom high refractive layer may be disposed on the first bottom high refractive layer, and the third bottom high refractive layer may be disposed on the second bottom high refractive layer.

In an embodiment, the second thickness may be greater than the third thickness, and the third thickness may be greater than the first thickness.

In an embodiment, the bottom low refractive layer may include a first bottom low refractive layer having a fourth thickness, a second bottom low refractive layer having a fifth thickness, and a third bottom low refractive layer having a sixth thickness, and a thickness of the top high refractive layer may be greater than each of the fourth to sixth thicknesses.

In an embodiment, a thickness of the top high refractive layer may be greater than a sum of the fourth to sixth thicknesses.

In an embodiment, the first bottom low refractive layer may be disposed on the first low high refractive layer, the second bottom low refractive layer may be disposed on the second bottom high refractive layer, and the third bottom low refractive layer may be disposed on the third bottom high refractive layer.

In an embodiment, the fourth thickness may be greater than the fifth thickness, and the fifth thickness may be greater than the sixth thickness.

In an embodiment, a refractive index of each of the bottom high refractive layer and the top high refractive layer may be about 1.9 to about 2.3.

In an embodiment, the bottom high refractive layer and the top high refractive layer may include aluminum silicon nitride (Al—Si—N).

In an embodiment, a refractive index of the bottom low refractive layer may be about 1.41 to about 1.54.

In an embodiment, the bottom low refractive layer may include silicon oxide (Si—O).

A window module according to another embodiment may include a window, at least one bottom high refractive layer disposed on the window, at least one bottom low refractive layer disposed on the bottom high refractive layer, a top high refractive layer disposed on the bottom low refractive layer, a capping layer disposed on the top high refractive layer, and an anti-fingerprint layer disposed on the capping layer. A thickness of the top high refractive layer may be greater than a thickness of the bottom high refractive layer and a thickness of the bottom low refractive layer.

In an embodiment, the window module may further include a top low refractive layer disposed between the top high refractive layer and the capping layer.

In an embodiment, a sum of a thickness of the top low refractive layer, a thickness of the capping layer, and a thickness of the anti-fingerprint layer may be a same as a distance between a top surface of the anti-fingerprint layer and a top surface of the top high refractive layer.

In an embodiment, a thickness of the top high refractive layer may be about 225 nm to about 375 nm.

In an embodiment, the bottom high refractive layer may include a first bottom high refractive layer having a first thickness, a second bottom high refractive layer having a second thickness, and a third bottom high refractive layer having a third thickness, and a thickness of the top high refractive layer may be greater than each of the first to third thicknesses.

In an embodiment, a thickness of the top high refractive layer may be greater than a sum of the first to third thicknesses.

In an embodiment, the first bottom high refractive layer may be disposed on the window, the second bottom high refractive layer may be disposed on the first bottom high refractive layer, and the third bottom high refractive layer may be disposed on the second bottom high refractive layer.

In an embodiment, the second thickness may be greater than the third thickness, and the third thickness may be greater than the first thickness.

In an embodiment, the first thickness may be about 15 nm to about 25 nm, the second thickness may be about 157 nm to about 197 nm, the third thickness may be about 41 nm to about 69 nm, and a thickness of the top high refractive layer may be about 255 nm to about 375 nm.

In an embodiment, the bottom low refractive layer may include a first bottom low refractive layer having a fourth thickness, a second bottom low refractive layer having a fifth thickness, and a third bottom low refractive layer having a sixth thickness, and a thickness of the top high refractive layer may be greater than each of the fourth to sixth thicknesses.

In an embodiment, a thickness of the top high refractive layer may be greater than a sum of the fourth to sixth thicknesses.

In an embodiment, the first bottom low refractive layer may be disposed on the first bottom high refractive layer, the second bottom low refractive layer may be disposed on the second bottom high refractive layer, and the third bottom low refractive layer may be disposed on the third bottom high refractive layer.

In an embodiment, the fourth thickness may be greater than the fifth thickness, and the fifth thickness may be greater than the sixth thickness.

In an embodiment, a refractive index of each of the bottom high refractive layer and the top high refractive layer may be about 1.9 to about 2.3.

In an embodiment, the bottom high refractive layer and the top high refractive layer may include aluminum silicon nitride (Al—Si—N).

In an embodiment, a refractive index of each of the bottom low refractive layer may be about 1.41 to about 1.54.

In an embodiment, the bottom low refractive layer may include silicon oxide (Si—O).

A display device according to an embodiment may include a display panel configured to display image and a window module disposed on the display panel. The window module may include a window, at least one bottom high refractive layer disposed on the window, at least one bottom low refractive layer disposed on the bottom high refractive layer, a top high refractive layer disposed on the bottom low refractive layer, a capping layer disposed on the top high refractive layer, and an anti-fingerprint layer disposed on the capping layer. A distance between a top surface of the anti-fingerprint layer and a top surface of the top high refractive layer may be less than about 200 nm.

In an embodiment, a distance between a top surface of the anti-fingerprint layer and a top surface of the top high refractive layer may be about 100 nm to about 150 nm.

In an embodiment, a distance between a top surface of the anti-fingerprint layer and a top surface of the top high refractive layer may be less than a thickness of the top high refractive layer.

In an embodiment, a thickness of the top high refractive layer may be about 225 nm to about 375 nm.

In an embodiment, the display device may further include a top low refractive layer disposed between the top high refractive layer and the capping layer.

In an embodiment, a sum of a thickness of the top low refractive layer, a thickness of the capping layer, and a thickness of the anti-fingerprint layer may be a same as a distance between a top surface of the anti-fingerprint layer and a top surface of the top high refractive layer.

An electronic device according to an embodiment may include a display device and a power module configured to provide power to the display device. The display device according to an embodiment may include a display panel configured to display image and a window module disposed on the display panel. The window module may include a window, at least one bottom high refractive layer disposed on the window, at least one bottom low refractive layer disposed on the bottom high refractive layer, a top high refractive layer disposed on the bottom low refractive layer, a capping layer disposed on the top high refractive layer, and an anti-fingerprint layer disposed on the capping layer. A distance between a top surface of the anti-fingerprint layer and a top surface of the top high refractive layer may be less than about 200 nm.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A window module comprising:
a window;
at least one bottom high refractive layer on the window;
at least one bottom low refractive layer on the bottom high refractive layer;
a top high refractive layer on the bottom low refractive layer;
a capping layer on the top high refractive layer; and
an anti-fingerprint layer on the capping layer,
wherein a distance between a top surface of the anti-fingerprint layer and a top surface of the top high refractive layer is less than about 200 nm.

2. The window module of claim 1, wherein the distance between the top surface of the anti-fingerprint layer and the top surface of the top high refractive layer is less than a thickness of the top high refractive layer.

3. The window module of claim 1, further comprising a top low refractive layer between the top high refractive layer and the capping layer.

4. The window module of claim 3, wherein a sum of a thickness of the top low refractive layer, a thickness of the capping layer, and a thickness of the anti-fingerprint layer is same as the distance between the top surface of the anti-fingerprint layer and the top surface of the top high refractive layer.

5. The window module of claim 1, wherein the bottom high refractive layer comprises a first bottom high refractive layer having a first thickness, a second bottom high refractive layer having a second thickness, and a third bottom high refractive layer having a third thickness, and
wherein a thickness of the top high refractive layer is greater than each of the first to third thicknesses.

6. The window module of claim 5, wherein the thickness of the top high refractive layer is greater than a sum of the first to third thicknesses.

7. The window module of claim 5, wherein the first bottom high refractive layer is on the window,
wherein the second bottom high refractive layer is on the first bottom high refractive layer, and
wherein the third bottom high refractive layer is on the second bottom high refractive layer.

8. The window module of claim 7, wherein the second thickness is greater than the third thickness, and
wherein the third thickness is greater than the first thickness.

9. The window module of claim 5, wherein the bottom low refractive layer comprises a first bottom low refractive layer having a fourth thickness, a second bottom low refractive layer having a fifth thickness, and a third bottom low refractive layer having a sixth thickness, and
wherein the thickness of the top high refractive layer is greater than each of the fourth to sixth thicknesses.

10. The window module of claim 9, wherein the thickness of the top high refractive layer is greater than a sum of the fourth to sixth thicknesses.

11. The window module of claim 9, wherein the first bottom low refractive layer is on the first bottom high refractive layer,
wherein the second bottom low refractive layer is on the second bottom high refractive layer, and
wherein the third bottom low refractive layer is on the third bottom high refractive layer.

12. The window module of claim 11, wherein the fourth thickness is greater than the fifth thickness, and
wherein the fifth thickness is greater than the sixth thickness.

13. The window module of claim 1, wherein a refractive index of each of the bottom high refractive layer and the top high refractive layer is about 1.9 to about 2.3.

14. The window module of claim 13, wherein the bottom high refractive layer and the top high refractive layer each comprise aluminum silicon nitride (Al—Si—N).

15. The window module of claim 1, wherein a refractive index of the bottom low refractive layer is about 1.41 to about 1.54.

16. The window module of claim 15, wherein the bottom low refractive layer comprises silicon oxide (Si—O).

17. A window module comprising:
a window;
at least one bottom high refractive layer on the window;
at least one bottom low refractive layer on the bottom high refractive layer;
a top high refractive layer on the bottom low refractive layer;
a capping layer on the top high refractive layer; and
an anti-fingerprint layer on the capping layer,
wherein a thickness of the top high refractive layer is greater than each of a thickness of the bottom high refractive layer and a thickness of the bottom low refractive layer.

18. The window module of claim 17, further comprising a top low refractive layer between the top high refractive layer and the capping layer.

19. The window module of claim 18, wherein a sum of a thickness of the top low refractive layer, a thickness of the capping layer, and a thickness of the anti-fingerprint layer is same as a distance between a top surface of the anti-fingerprint layer and a top surface of the top high refractive layer.

20. An electronic device comprising:
a display device; and
a power module configured to provide power to the display device,
wherein the display device comprises:
a display panel configured to display an image; and
a window module on the display panel,
wherein the window module comprises:
a window;
at least one bottom high refractive layer on the window;
at least one bottom low refractive layer on the bottom high refractive layer;
a top high refractive layer on the bottom low refractive layer;
a capping layer on the top high refractive layer; and
an anti-fingerprint layer on the capping layer, and
wherein a distance between a top surface of the anti-fingerprint layer and a top surface of the top high refractive layer is less than about 200 nm.
